(19) United States
(12) Patent Application Publication
(10) Pub. No.: US 2023/0207490 A1
(43) Pub. Date: Jun. 29, 2023

(54) SURFACE-MOUNT DEVICE WIRE BONDING IN SEMICONDUCTOR DEVICE ASSEMBLIES

(71) Applicant: Micron Technology, Inc., Boise, ID (US)

(72) Inventors: Yung Sheng Zou, Taichung (TW); Yun Ting Hsu, Taichung (TW)

(21) Appl. No.: 17/976,625

(22) Filed: Oct. 28, 2022

Related U.S. Application Data
(60) Provisional application No. 63/293,438, filed on Dec. 23, 2021.

(51) Int. Cl. H01L 23/58; H01L 23/00

(52) U.S. Cl. CPC H01L 23/58; H01L 24/08; H01L 24/05; H01L 24/06; H01L 24/49; H01L 24/48; H01L 2224/04042; H01L 2224/05644; H01L 2224/0603; H01L 2224/06102; H01L 2224/08113; H01L 2224/48091; H01L 2224/48229; H01L 2224/49107

(57) ABSTRACT

A semiconductor device assembly including a substrate, a surface-mount device (SMD) electrical component attached to the substrate is provided. The SMD electrical component includes a first contact and a second contact, and at least a first wire bond electrically and physically coupled directly to the first contact.

### CROSS-REFERENCE TO RELATED APPLICATION(S)

The present application claims priority to U.S. Provisional Patent Application No. 63/293,438, filed Dec. 23, 2021, the disclosure of which is incorporated herein by reference in its entirety.

### TECHNICAL FIELD

The present disclosure relates to surface-mount devices for semiconductor device assemblies, and more particularly relates to surface-mount device wire bonding in semiconductor device assemblies.

### BACKGROUND

The trend to manufacture ever smaller electronic devices has led to significantly thinner semiconductor devices densely packed on a device wafer or substrate. With the addition of discrete circuit elements such as capacitors and resistors to an already very limited space of the semiconductor device assembly, finding ways to accommodate discrete circuit elements while reducing the semiconductor device assembly size has become a challenge for at least several reasons as listed below. For example, using solder paste to connect discrete circuit elements to copper pads requires several reflow heating procedures to thoroughly melt the solder paste for obtaining a good contact between the paste and discrete element terminals which still results in one or more terminals becoming detached from the copper pads. Also, use of asymmetric via designs to tighten the space between discrete circuit elements and semiconductor devices has resulted in uneven heating of solder paste on the terminals causing discrete circuit elements to eventually fail or detach from the semiconductor device assembly. Moreover, discrete circuit elements are generally arranged along an edge of the semiconductor device assembly taking valuable space away from additional circuitry or semiconductor devices and/or requiring larger sized electronic devices to fit the semiconductor device assembly having discrete circuit elements.

### BRIEF DESCRIPTION OF THE DRAWINGS

FIG. 1A is a simplified schematic cross-sectional view of an exemplary semiconductor device assembly in accordance with an embodiment of the present disclosure.

FIG. 1B is a simplified schematic cross-sectional view of an exemplary semiconductor device assembly in accordance with an embodiment of the present disclosure.

FIG. 2 is a simplified schematic cross-sectional view of an exemplary semiconductor device assembly in accordance with an embodiment of the present disclosure.

FIG. 3 is a simplified schematic cross-sectional view of an exemplary semiconductor device assembly in accordance with an embodiment of the present disclosure.

FIG. 4 is a schematic view showing an exemplary system that includes a semiconductor device assembly configured in accordance with an embodiment of the present disclosure.

FIG. 5 is a flow chart illustrating an exemplary method of making a semiconductor device assembly in accordance with an embodiment of the present disclosure.

While the disclosure is susceptible to various modifications and alternative forms, specific embodiments have been shown by way of example in the drawings and will be described in detail herein. However, it should be understood that the disclosure is not intended to be limited to the particular forms disclosed. Rather, the intention is to cover all modifications, equivalents and alternatives falling within the scope of the disclosure as defined by the appended claims.

### DETAILED DESCRIPTION

Specific details of several embodiments of semiconductor devices, and associated systems and methods, are described below. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In this disclosure, numerous specific details are discussed to provide a thorough and enabling description for embodiments of the present disclosure. One of ordinary skill in the art will recognize that the disclosure can be practiced without one or more of the specific details. Well-known structures and/or operations often associated with semiconductor devices may not be shown and/or may not be described in detail to avoid obscuring other aspects of the disclosure. In general, it should be understood that various other devices, systems, and/or methods in addition to those specific embodiments disclosed herein may be within the scope of the present disclosure.

The term “semiconductor device assembly” can refer to an assembly of one or more semiconductor devices, semiconductor device packages, and/or substrates, which may include interposers, supports, and/or other suitable substrates. The semiconductor device assembly may be manufactured as, but not limited to, discrete package form, strip or matrix form, and/or wafer panel form. The term “semiconductor device” generally refers to a solid-state device that includes semiconductor material. A semiconductor device can include, for example, a semiconductor substrate, wafer, panel, or a single die from a wafer or substrate. A semiconductor device may further include one or more device layers deposited on a substrate. A semiconductor device may refer herein to a semiconductor die, but semiconductor devices are not limited to semiconductor dies.

The term “semiconductor device package” can refer to an arrangement with one or more semiconductor devices incorporated into a common package. A semiconductor package can include a housing or casing that partially or completely encapsulates at least one semiconductor device. A semiconductor package can also include a substrate that carries one or more semiconductor devices. The substrate may be attached to or otherwise incorporate within the housing or casing. The term “substrate” as described in the present disclosure can refer to a package substrate or printed circuit board (PCB) in some embodiments, or may refer to a semiconductor device (e.g., semiconductor die) providing support for another device or circuit element in other embodiments.

As set forth above, the use of solder paste to connect discrete circuit elements (e.g., surface mount devices) to copper pads can require several reflow heating procedures to thoroughly melt the solder paste for obtaining a good contact between the paste and discrete element terminals. In this process of multiple rounds of reflow heating, one or more terminals of a discrete circuit element can become detached from the corresponding copper pad. Also, the use of asymmetric via designs to tighten the space between discrete circuit elements and semiconductor devices can result in uneven heating of solder paste on the terminals causing discrete circuit elements to eventually fail or detach from the semiconductor device assembly. Moreover, discrete circuit elements are generally arranged along an edge of the semiconductor device assembly taking valuable space away from additional circuitry or semiconductor devices and/or requiring larger sized electronic devices (e.g., cell phones, portable computing devices, etc.) to fit the semiconductor device assembly having discrete circuit elements.

Embodiments of the present disclosure can address these problems and others by directly connecting or bonding surface mount device (SMD) electrical components to other circuits in a semiconductor assembly or package using, for example, wire bonding. The use of solder paste to attach the SMD electrical components may thereby be reduced or avoided. Moreover, directly wire bonding SMD circuit elements can allow them to be arranged vertically or multiply stacked in a semiconductor assembly, further saving space. By using wire bonds to connect SMD electrical devices, the foregoing difficulties of these devices becoming detached from copper pads, the uneven heating of solder paste thereon causing failure or detaching from the semiconductor device assembly, and the loss of valuable space on the semiconductor device assembly can be avoided and/or ameliorated, as is set forth in greater detail below.

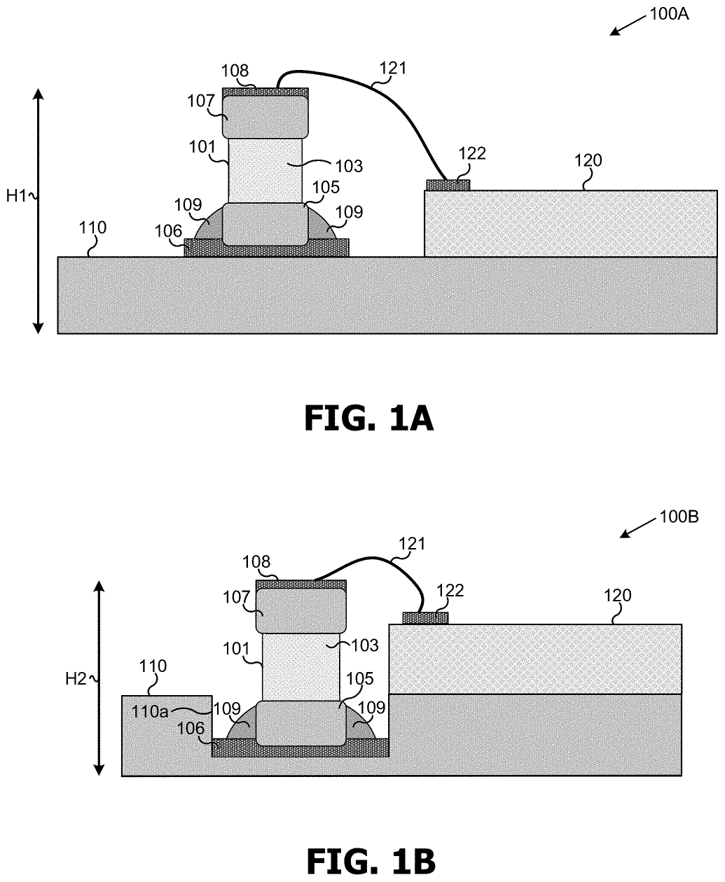

FIG. 1A is a simplified schematic cross-sectional view of an exemplary semiconductor device assembly 100A in accordance with an embodiment of the present disclosure. As can be seen with reference to FIG. 1A, semiconductor die 120 and surface-mount device (SMD) 101 are attached to substrate 110. The semiconductor die 120 may be, for example, one or more semiconductor chip(s), controller(s), stacked or 3D semiconductor devices, and the like. The surface-mount device 101 may be one or more individual circuit elements or electrical components, for example, either passive (resistor, capacitor, inductor) or active (transistor or vacuum tube) components. The exemplary surface-mount device 101 includes a body 103, first contact 105 and second contact 107. Other surface mount devices may have other numbers of contacts, of course, as will be readily understood by those of skill in the art.

The semiconductor device assembly 100A may include a first interconnection formed between the first contact 105 and substrate 110. The first interconnection includes, for example, one or more mounting pads 106 to connect the first contact 105 to electrical circuits in the substrate 110. Alternatively, or additionally, the first interconnection may be made through, for example, one or more wires, traces, or conductive layers.

The body 103 and/or first contact 105 of the surface-mount device 101 may be attached to mounting pad 106 through adhesive material 109 (e.g., solder). The body 103 of the surface-mount device 101 may be attached to the substrate 110 in a vertical or horizontal orientation. According to one aspect of the subject disclosure, the vertical arrangement of the surface-mount device 101 can provide a reduction in plan-area of the assembly 100A.

Examples of metals which could be used in the formation of mounting pad 106 include copper, aluminum, tungsten, tin, silver, gold or any of the six platinum metals (i.e., Ru, Rh, Pd, Os, Ir, or Pt). Examples of materials which could be used in the formation of adhesive material 109 include one or more of tin, silver, copper, zinc, manganese, antimony, lead, cobalt, indium, aluminum, and the like and any alloy of the above materials. Any convenient deposition method may be used in formation of mounting pad 106 and adhesive material 109, including chemical vapor deposition (CVD), vapor deposition polymerization (VDP), physical vapor deposition (PVD), e.g., sputtering, or electroplating.

The semiconductor device assembly 100A may include a second interconnection formed between the second contact 107 and semiconductor die 220. The second interconnection includes, for example, one or more pads 122, wiring 121 (e.g. wire bonding) and conductive layers 108 to connect the second contact 107 to the semiconductor die 120.

Examples of metals which could be used in the formation of conductive layers 108, wiring 121 (e.g. wire bonding), and pad 122 include copper, aluminum, tungsten, tin, silver, gold or any of the six platinum metals (i.e., Ru, Rh, Pd, Os, Ir, or Pt), and the like. Any convenient deposition method may be used in formation of conductive layers 108, wiring 121, and pad 122, including spin coating, chemical vapor deposition (CVD), atomic layer deposition (ALD), vapor deposition polymerization (VDP), or physical vapor deposition (PVD), e.g., sputtering, or electroplating.

The spacing between surface-mount device 101 and semiconductor die 120 and the amount of material used for forming mounting pad 106 and pad 108 may be adjusted as desired to control package height H1 and/or package plan area thereby providing additional space for a larger semiconductor die 120 or smaller package substrate 110. Moreover, the vertical position and amount of material used to form interconnect (e.g., mounting pad 106) to connect first contact 105 to substrate 110 may be adjusted based on the dimensions of the surface-mount device 101 or a desired surface area or contact surface between first contact 105 and substrate 110.

FIG. 1B is a simplified schematic cross-sectional view of an exemplary semiconductor device assembly 100B in accordance with an embodiment of the present disclosure. As can be seen with reference to FIG. 1B, semiconductor die 120 and surface-mount device 101 are attached to substrate 110 with a first interconnection made between first contact 105 and substrate 110 through, for example, mounting pad 106. Further, a second interconnection may be made between second contact 107 and semiconductor die 120 through, for example, one or more pads 122, wiring 121 (e.g. wire bonding) and conductive layers 108. The body 103 and/or first contact 105 of the surface-mount device 101 may be attached to mounting pad 106 through adhesive material 109.

The body 103 of the surface-mount device 101 may be attached to the substrate 110 in a vertical or horizontal orientation. The body 103, first contact 105 and/or the mounting pad 106 of the discrete semiconductor element 101 may be partially or fully embedded in a cavity or trench 110a formed in the substrate 110. The trench 110a may provide control of package height H2 and/or package plan area thereby providing additional space for a larger semiconductor die 120 or smaller package substrate 110. Moreover, the dimensions of the trench 110a may be adjusted based on the dimensions of the surface-mount device 101 or a desired surface area or contact surface between mounting pad 106, first contact 105 and substrate 110. Thus, the spacing between surface-mount device 101 and semiconductor die 120 and the amount of material used for forming mounting pad 106 and pad 108 may be adjusted as desired to control package height H2 and/or package plan area thereby providing additional space for a larger semiconductor die 120 or smaller package substrate 110. Moreover, the vertical position and amount of material used to form interconnect (e.g. conductive layer 108, pad 122, or wiring 121) to connect second contact 107 to semiconductor die 120 may be adjusted based on the dimensions of the surface-mount device 101 or a desired surface area or contact surface between second contact 107 and semiconductor die 120.

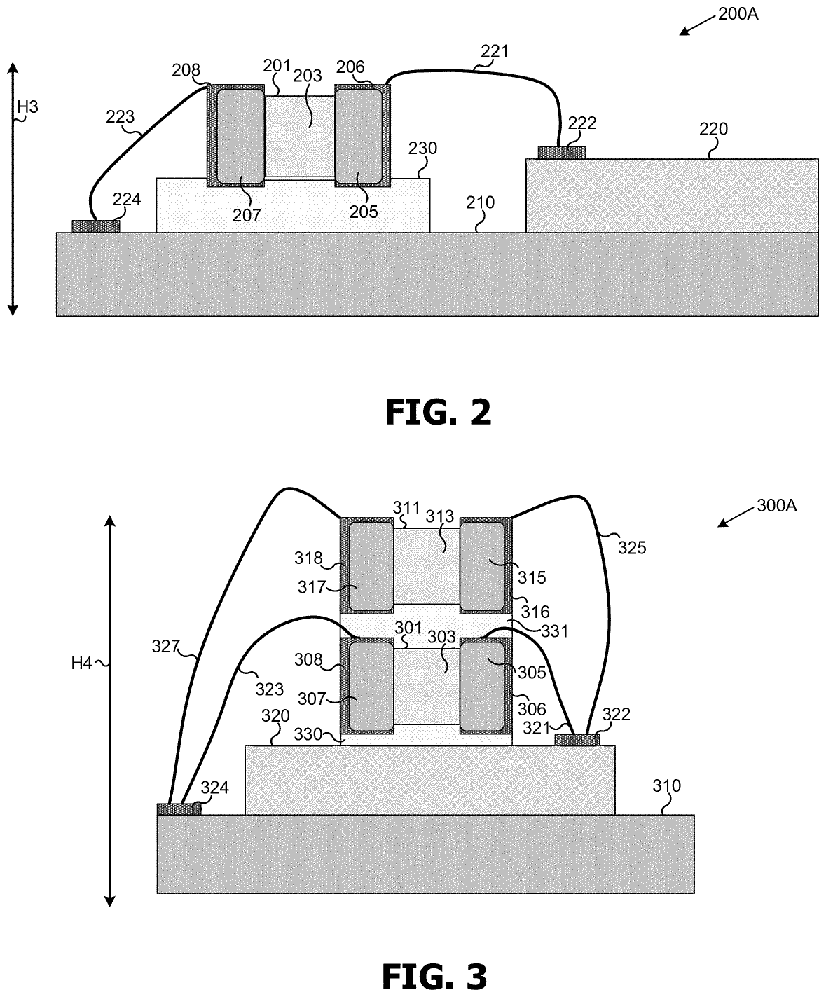

FIG. 2 is a simplified schematic cross-sectional view of an exemplary semiconductor device assembly 200A in accordance with an embodiment of the present disclosure. As can be seen with reference to FIG. 2, semiconductor die 220 and surface-mount device (SMD) 201 are attached to substrate 210. The semiconductor die 220 may be, for example, one or more semiconductor chip(s), controller(s), stacked or 3D semiconductor devices, and the like. The surface-mount device 201 may be one or more individual circuit elements or electrical components, for example, either passive (resistor, capacitor, inductor) or active (transistor or vacuum tube) components. The exemplary surface-mount device 201 includes a body 203, first contact 205 and second contact 207.

The semiconductor device assembly 200A may include a first interconnection formed between the first contact 205 and semiconductor die 220. The first interconnection includes, for example, one or more pads 222, wiring 221 (e.g. wire bonding) and conductive layers 206 to connect the first contact 205 to the semiconductor die 220.

The semiconductor device assembly 200A may include second interconnection formed between the second contact 207 and substrate 210. The second interconnection includes, for example, one or more pads 224, wiring 223 (e.g. wire bonding) and conductive layers 208 to connect the second contact 207 to the substrate 210.

Examples of metals which could be used in the formation of conductive layers 206 and 208, pads 222 and 224, and wiring 222 and 223 (e.g. wire bonding) include copper, aluminum, tungsten, tin, silver, gold or any of the six platinum metals (i.e., Ru, Rh, Pd, Os, Ir, or Pt), and the like. Any convenient deposition method may be used in formation of conductive layers 206 and 208, pads 222 and 224, and wiring 222 and 223, including spin coating, chemical vapor deposition (CVD), atomic layer deposition (ALD), vapor deposition polymerization (VDP), or physical vapor deposition (PVD), e.g., sputtering, or electroplating.

At least one of the body 203, first contact 205 and second contact 207 of surface-mount device 201 may be attached to the substrate 210 through die attached film or non-conductive film 230. The body 203 of the surface-mount device 201 may be attached to the substrate 210 in a vertical or horizontal orientation. The body 203, first contact 205 and second contact 207 of the discrete semiconductor element 101 may be partially or fully embedded in non-conductive film 230. The body 203, first contact 205 and second contact 207 of surface-mount device 201 may be sandwiched between, and attached to substrate 210, by non-conductive film 230. The amount of non-conductive film 230 formed on substrate 210 may be adjusted based on the dimensions of the surface-mount device 201 (e.g. package height H3) or a desired surface area or contact surface between body 203 and conductive layers 206 and 208 and non-conductive film 230. The spacing between surface-mount device 201 and semiconductor die 220 and the amount of material used for forming conductive layers 206 and 208 may be adjusted as desired to control package height H3 and/or package plan area thereby providing additional space for a larger semiconductor die 220 or smaller package substrate 210. Moreover, the horizontal position and amount of material used to form interconnects (e.g. conductive layers 206 and 208, pads 222 and 224, or wiring 221 and 223) to connect first and second contacts 205 and 207 to semiconductor die 220 and substrate 210 may be adjusted based on the dimensions of the surface-mount device 201 or a desired surface area or contact surface between first and second contacts 205 and 207 and semiconductor die 220 and substrate 210.

Examples of material which could be used in the formation of the non-conductive film 230 may be selected from one of die attach film (DAF), film on wire (FOW), resins, adhesives, or a composite of materials such as industrial plastics and polymers suitable for forming an adhesion and protective layer including thermoset resins, gel elastomers, encapsulants, potting compounds, composites, and optical grade materials. Any convenient deposition method may be used, including spin coating, chemical vapor deposition (CVD), atomic layer deposition (ALD), vapor deposition polymerization (VDP), or physical vapor deposition (PVD).

Although the embodiment above shows one connection to the substrate and one connection to the die, other arrangements are possible, including connections to a plurality of substrates, a plurality of circuit elements, a plurality of surface mount devices, a plurality of mounting pads, a plurality of metal pads, and/or a plurality of dies. In some embodiments, both connections of the surface mount device are to one substrate or to one die (or other circuit element), or both connections are to different substrates or to different dies (or different circuit elements). In some embodiments, the surface mount device may include more than one connection to one or more substrates and more than one connection to one or more dies (or one or more other circuit elements). In some embodiments, the surface mount device may include more than one connection to one or more substrates and one or no connections to a die (or other circuit element). In some embodiments, the surface mount device may include more than one connection to one or more dies (or one or more other circuit elements) and one or no connections to a substrate. Although only vertical or horizontal arrangements are shown for in an embodiment of the surface mount device, other arrangements are possible, for example, horizontally arrangement of some or all surface mount devices on one or more substrates or dies, or vertical arrangement of some or all surface mount devices on one or more substrates or dies, or any combination of the above.

FIG. 3 is a simplified schematic cross-sectional view of an exemplary semiconductor device assembly 300A in accordance with an embodiment of the present disclosure. With reference to FIGS. 2-3, FIG. 3 further includes a plurality of surface-mount devices 301, 311, . . . etc., stacked on semiconductor die 320 with non-conductive films 330, 331, . . . etc., interposed between each surface-mount devices 301, 311 and between the bottom surface-mount device 301 and semiconductor die 320. The semiconductor assembly 200A of FIG. 2 yields smaller package heights H3 in exchange for larger package plan area, whereas the stacked semiconductor assembly 300A of FIG. 3 yields smaller package plan area in exchange for larger package height H4.

The semiconductor device assembly 300A may include a third interconnection formed between the third contact 315 and semiconductor die 320. The third interconnection includes, for example, one or more pads 322, wiring 325 (e.g. wire bonding) and conductive layers 316 to connect the third contact 315 to the semiconductor die 320.

The semiconductor device assembly 300A may include fourth interconnection formed between the fourth contact 317 and substrate 310. The fourth interconnection includes, for example, one or more pads 324, wiring 327 (e.g. wire bonding) and conductive layers 318 to connect the fourth contact 317 to the substrate 310.

Examples of material which could be used in the formation of the non-conductive film 330 may be selected from one of die attach film (DAF), film on wire (FOW), resins, adhesives, or a composite of materials such as industrial plastics and polymers suitable for forming an adhesion and protective layer including thermoset resins, gel elastomers, encapsulants, potting compounds, composites, and optical grade materials. Any convenient deposition method may be used, including spin coating, chemical vapor deposition (CVD), atomic layer deposition (ALD), vapor deposition polymerization (VDP), or physical vapor deposition (PVD).

Examples of metals which could be used in the formation of conductive layers 306 and 308, pads 322 and 324, and wiring 322 and 323 (e.g. wire bonding) include copper, aluminum, tungsten, tin, silver, gold or any of the six platinum metals (i.e., Ru, Rh, Pd, Os, Ir, or Pt). Any convenient deposition method may be used, including spin coating, chemical vapor deposition (CVD), atomic layer deposition (ALD), vapor deposition polymerization (VDP), physical vapor deposition (PVD), e.g., sputtering, or electroplating.

The bottom or first surface-mount device 301 is formed directly over and attached to semiconductor die 320 through die attached film or non-conductive film 330. Each subsequent second, third, fourth etc., surface-mount device 311 . . . etc., may be sandwiched together by die attached film or non-conductive film 331 . . . etc., and stacked to form the semiconductor device assembly 300A.

Examples of material which could be used in the formation of the non-conductive film 331 and subsequent non-conductive films may be selected from one of die attach film (DAF), film on wire (FOW), resins, adhesives, or a composite of materials such as industrial plastics and polymers suitable for forming an adhesion and protective layer including thermoset resins, gel elastomers, encapsulants, potting compounds, composites, and optical grade materials. Any convenient deposition method may be used, including spin coating, chemical vapor deposition (CVD), atomic layer deposition (ALD), vapor deposition polymerization (VDP), or physical vapor deposition (PVD).

Referring to FIG. 3, the first surface-mount device 301 includes body 303, first contact 305 and second contact 307. The body 303, first contact 305 and second contact 307 may be partially or fully embedded in non-conductive film 330. The body 303, first contact 305 and second contact 307 of surface-mount device 301 may be sandwiched between, and attached to semiconductor die 320, by non-conductive film 330. The amount of non-conductive film 330 formed on the semiconductor die 320 may be adjusted based on the dimensions of the surface-mount device 301 (e.g. package height H4) or a desired surface area or contact surface between body 303 and conductive layers 306 and 308 and non-conductive film 330. The spacing between surface-mount device 301 and semiconductor die 320 and the amount of material used for forming conductive layers 306 and 308 may be adjusted as desired to control package height H4. Moreover, the horizontal position and amount of material used to form interconnects (e.g. conductive layers 306 and 308, pads 322 and 324, or wiring 321 and 323) to connect first and second contacts 305 and 307 to semiconductor die 320 and substrate 310 may be adjusted based on the dimensions of the surface-mount device 301 or a desired surface area or contact surface between first and second contacts 305 and 307 and semiconductor die 320 and substrate 310.

The second surface-mount device 311 includes body 313, first contact 315 and second contact 317. The body 313, first contact 315 and second contact 317 may be partially or fully embedded in non-conductive film 331. The body 313, first contact 315 and second contact 317 of the second surface-mount device 311 may be sandwiched between and attached to the first surface-mount device 301 by non-conductive film 331. The amount of non-conductive film 331 formed on the first surface-mount device 301 may be adjusted based on the dimensions of the first and second surface-mount devices 301 and 311, a desired package height H4, or a desired surface area or contact surface between body 313 and conductive layers 316 and 318 and non-conductive film 331. The spacing between second surface-mount device 311 and first surface-mount device 301 and the amount of material used for forming conductive layers 316 and 318 may be adjusted as desired to control package height H4. Moreover, the horizontal position and amount of material used to form interconnects (e.g. conductive layers 316 and 318, pads 322 and 324, or wiring 325 and 327) to connect first and second contacts 315 and 317 to semiconductor die 320 and substrate 310 may be adjusted based on the dimensions of the second surface-mount device 311 or a desired surface area or contact surface between first and second contacts 315 and 317 and semiconductor die 320 and substrate 310.

Although the embodiment above shows one connection from each of two surface mount devices to the substrate and one connection to the die, other arrangements are possible, including connections to a plurality of substrates, a plurality of circuit elements, a plurality of surface mount devices, a plurality of mounting pads, a plurality of metal pads, and/or a plurality of dies. In some embodiments, both connections of each surface mount device are to one substrate or to one die (or other circuit element), or both connections of each surface mount device are to different substrates or to different dies (or different circuit elements). In some embodiments, each surface mount device may include more than one connection to one or more substrates and more than one connection to one or more dies (or one or more other circuit elements). In some embodiments, each surface mount device may include more than one connection to one or more substrates and one or no connections to a die (or other circuit element). In some embodiments, each surface mount device may include more than one connection to one or more dies (or one or more other circuit elements) and one or no connections to a substrate. Although only vertical or horizontal arrangements are shown for in an embodiment of the surface mount device, other arrangements are possible, for example, horizontally arrangement of some or all surface mount devices on one or more substrates or dies, or vertical arrangement of some or all surface mount devices on one or more substrates or dies, or any combination of the above.

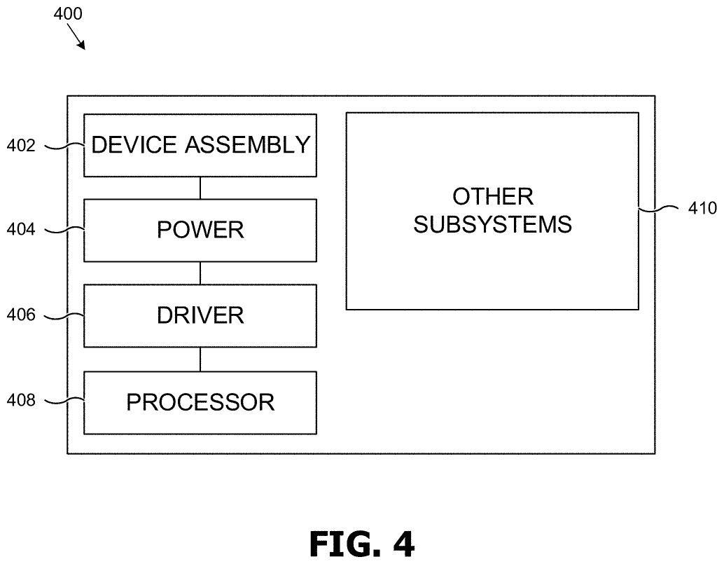

FIG. 4 is a schematic view showing an exemplary system that includes a semiconductor device assembly configured in accordance with an embodiment of the present disclosure. Any one of the exemplary semiconductor devices and semiconductor device assemblies described above with reference to FIGS. 1A-1B and 2-3 may be incorporated into any of a myriad of larger and/or more complex systems, a representative example of which is system 400 shown schematically in FIG. 4. The system 400 may include semiconductor device assembly (e.g., or a discrete semiconductor device) 402, power source 404, driver 406, processor 408, and/or other subsystems or components 410. The semiconductor device assembly 402 may include features generally similar to those of the semiconductor devices described above with reference to FIGS. 1A-1B and 2-3. The resulting system 400 may perform any of a wide variety of functions, such as memory storage, data processing, and/or other suitable functions. Accordingly, representative systems 400 may include, without limitation, hand-held devices (e.g., mobile phones, tablets, digital readers, and digital audio players), computers, vehicles, appliances and other products. Components of the system 400 may be housed in a single unit or distributed over multiple, interconnected units (e.g., through a communications network). The components of the system 400 may also include remote devices and any of a wide variety of computer readable media.

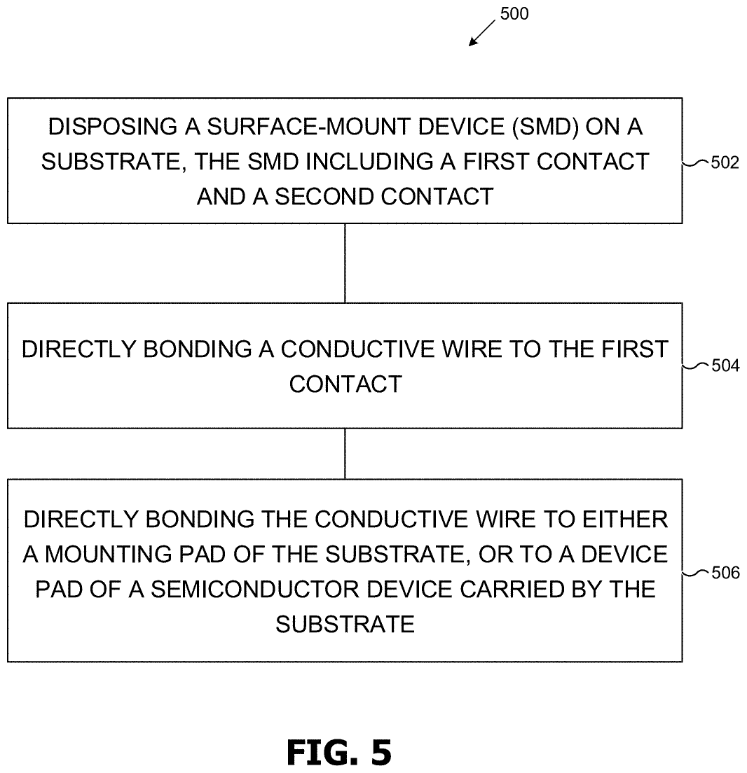

FIG. 5 is a flow chart illustrating an exemplary method of making a semiconductor device assembly. The exemplary method is provided by way of example, as there are a variety of ways to carry out the method. Each box shown in FIG. 5 represents one or more processes, methods or subroutines, carried out in the exemplary method. FIGS. 1A-1B and 2-3 show exemplary embodiments of carrying out the method of FIG. 5. The exemplary method may begin at box 502. Further for explanatory purposes, the boxes of the example process 500 are described herein as occurring in serial, or linearly. However, multiple boxes of the example process 500 may occur in parallel. In addition, the boxes of the example process 500 may be performed a different order than the order shown and/or one or more of the boxes of the example process 500 may not be performed.

The exemplary method of FIG. 5 includes disposing a surface-mount device (SMD) on a substrate, the SMD including first contact and second contacts (box 502). In some exemplary embodiments, at least one first or second contact of the SMD may be horizontally or vertically mounted on the substrate or oriented such that an axis extending between the first contact and the second contact is perpendicular to a major surface of the substrate. The SMD device may be coupled or mounted to the substrate through a conductive (e.g. gold, copper, aluminum, etc.,) or non-conductive material (die attach film (DAF), film on wire (FOW), resins, adhesives, a composite of materials such as industrial plastics and polymers, etc.,). The conductive or non-conductive material may be deposited on the substrate to form one or more films, layers, or pads.

The method further includes directly bonding a conductive wire to the first contact (box 504). In some exemplary embodiments, the conductive wire may be replaced by or further comprise of one or more conductive films, layers or pads.

Examples of conductive materials which could be used in the formation of the conductive wire (e.g. wire bonding) include copper, aluminum, tungsten, tin, silver, gold or any of the six platinum metals (i.e., Ru, Rh, Pd, Os, Ir, or Pt). Examples of materials which could be used in the formation of adhesive material disposed on one or more contacts may include one or more of tin, silver, copper, zinc, manganese, antimony, lead, cobalt, indium, aluminum, and the like and any alloy of the above materials. Examples of material which could be used in the formation of the non-conductive material may be selected from one of die attach film (DAF), film on wire (FOW), resins, adhesives, or a composite of materials such as industrial plastics and polymers suitable for forming an adhesion and protective layer including thermoset resins, gel elastomers, encapsulants, potting compounds, composites, and optical grade materials.

The method further includes directly bonding the conductive wire to either a mounting pad of the substrate, or to a device pad of a semiconductor device carried by the substrate (box 506). The method may further include forming a semiconductor device assembly by stacking a plurality of SMD devices where each SMD device may be connected to one or more substrates, one or more mounting pads, one or more circuit elements, or one or more semiconductor dies.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” may refer to relative directions or positions of features in the semiconductor devices in view of the orientation shown in the Figures. For example, “upper” or “uppermost” may refer to a feature positioned closer to the top of a page than another feature. These terms, however, should be construed broadly to include semiconductor devices having other orientations, such as inverted or inclined orientations where top/bottom, over/under, above/below, up/down, and left/right may be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the present disclosure have been described herein for purposes of illustration, but that various modifications may be made without deviating from the scope of the present disclosure. Rather, in the foregoing description, numerous specific details are discussed to provide a thorough and enabling description for embodiments of the present disclosure. One skilled in the relevant art, however, will recognize that the disclosure may be practiced without one or more of the specific details. In other instances, well-known structures or operations often associated with memory systems and devices are not shown, or are not described in detail, to avoid obscuring other aspects of the present disclosure. In general, it should be understood that various other devices, systems, and methods in addition to those specific embodiments disclosed herein may be within the scope of the present disclosure.

What is claimed:

1. A semiconductor device assembly comprising:
a substrate including a mounting pad;
a surface-mount device (SMD) electrical component including a first contact and a second contact, the first contact electrically coupled to the mounting pad; and
a wire bond electrically and physically coupled directly to the second contact.

2. The semiconductor device assembly of claim 1, wherein the second contact comprises an outermost layer of gold.

3. The semiconductor device assembly of claim 1, wherein the mounting pad comprises material selected from the group consisting of copper, aluminum, tungsten, tin, silver, gold or platinum.

4. The semiconductor device assembly of claim 1, wherein the mounting pad is a first mounting pad, and wherein the wire bond is further electrically and physically coupled directly to a second mounting pad of the substrate.

5. The semiconductor device assembly of claim 1, further comprising a semiconductor device carried by the substrate and including a device pad, wherein the wire bond is further electrically and physically coupled directly to the device pad.

6. The semiconductor device assembly of claim 1, wherein the first contact is electrically coupled to the mounting pad by a solder joint.

7. The semiconductor device assembly of claim 1, wherein the second contact is substantially free from any solder material.

8. The semiconductor device assembly of claim 1, wherein the SMD electrical component is oriented such that an axis extending between the first contact and the second contact is perpendicular to a major surface of the substrate.

9. The semiconductor device assembly of claim 1, wherein the mounting pad is disposed in a cavity of the substrate, such that the SMD electrical component is at least partially recessed below an uppermost surface of the substrate.

10. A semiconductor device assembly, comprising:
a substrate;
a surface-mount device (SMD) electrical component attached to the substrate, the SMD electrical component including a first contact and a second contact;
a first wire bond electrically and physically coupled directly to the first contact; and
a second wire bond electrically and physically coupled directly to the second contact.

11. The semiconductor device assembly of claim 10, wherein the second contact of the SMD electrical component comprises an outermost layer of gold.

12. The semiconductor device assembly of claim 10, wherein the SMD electrical component is attached to the substrate by a non-conductive adhesive material.

13. The semiconductor device assembly of claim 10, wherein the SMD electrical component is a first SMD electrical component, and further comprising a second SMD electrical component vertically stacked over the first SMD electrical component and separated from the first SMD electrical component by a non-conductive adhesive material.

14. The semiconductor device assembly of claim 13, wherein the second SMD electrical component includes a third contact and a fourth contact, a third wire bond electrically and physically coupled directly to the third contact, and a fourth wire bond electrically and physically coupled directly to the fourth contact.

15. The semiconductor device assembly of claim 13, wherein the first wire bond and the second wire bond are at least partially encapsulated by the non-conductive adhesive material.

16. The semiconductor device assembly of claim 10, wherein at least one of the first wire bond and the second wire bond is further electrically and physically coupled directly to a mounting pad of the substrate.

17. The semiconductor device assembly of claim 10, further comprising a semiconductor device carried by the substrate, and wherein at least one of the first wire bond and the second wire bond is further electrically and physically coupled directly to a device pad of the semiconductor device.

18. The semiconductor device assembly of claim 10, wherein the first contact and second contact are each substantially free from any solder material.

19. A method of making a semiconductor device assembly, the method comprising:
disposing a surface-mount device (SMD) electrical component on a substrate, the SMD electrical component including a first contact and a second contact; and
directly bonding a conductive wire to the first contact.

20. The method of claim 19, further comprising directly bonding the conductive wire to either a mounting pad of the substrate, or to a device pad of a semiconductor device carried by the substrate.
